(19) United States
(12) Patent Application Publication
(10) Pub. No.: US 2026/0182024 A1
(43) Pub. Date: Jun. 25, 2026

(54) METHOD OF MANUFACTURING POLYCRYSTALLINE SILICON LAYER, DISPLAY DEVICE INCLUDING POLYCRYSTALLINE SILICON LAYER, METHOD OF MANUFACTURING DISPLAY DEVICE, AND ELECTRONIC DEVICE

(71) Applicant: Samsung Display Co., Ltd., Yongin-si (KR)

(72) Inventors: JONGHOON CHOI, Yongin-si (KR); HYOUNG SIK KIM, Yongin-si (KR); JI-HWAN KIM, Yongin-si (KR)

(21) Appl. No.: 19/422,251

(22) Filed: Dec. 16, 2025

(30) Foreign Application Priority Data
Dec. 19, 2024 (KR) 10-2024-0191698

(51) Int. Cl. H10D 86/01; H10D 30/01; H10D 86/60; H10K 59/12; H10K 59/121; H10P 14/20

(52) U.S. Cl. CPC H10D 86/0229; H10D 30/0314; H10D 30/0321; H10D 86/60; H10K 59/1201; H10K 59/1213; H10P 14/3454; H10P 14/3808; H10P 14/3411

(57) ABSTRACT

In a method of manufacturing a polycrystalline silicon layer, the method includes: forming an amorphous silicon layer on a substrate; dry cleaning the amorphous silicon layer by supplying a reaction gas to the amorphous silicon layer; and irradiating the amorphous silicon layer with a laser beam to form a polycrystalline silicon layer.

### CROSS-REFERENCE TO RELATED APPLICATION

The present application claims priority to and the benefit of Korean Patent Application No. 10-2024-0191698, filed on Dec. 19, 2024, in the Korean Intellectual Property Office, the entire disclosure of which is incorporated herein by reference.

### BACKGROUND

### 1. Field

Aspects of some embodiments of the present disclosure relate to a method of manufacturing a polycrystalline silicon layer, a display device including a polycrystalline silicon layer, a method of manufacturing a display device, and an electronic device.

### 2. Description of the Related Art

A display device includes a pixel circuit for each pixel, and the pixel circuit may include a thin-film transistor using silicon. As silicon constituting a thin-film transistor, amorphous silicon or polycrystalline silicon may be used as part of the pixel circuit. Thin film transistors using polycrystalline silicon have high electron mobility and excellent stability against light irradiation, compared to thin-film transistors using amorphous silicon.

Polycrystalline silicon may be produced by various methods, which can be largely divided into a method of directly depositing polycrystalline silicon and a method of depositing amorphous silicon, and then crystallizing the amorphous silicon.

The above information disclosed in this Background section is only for enhancement of understanding of the background and therefore the information discussed in this Background section does not necessarily constitute prior art.

### SUMMARY

Aspects of some embodiments include a method of manufacturing a polycrystalline silicon layer with relatively improved surface roughness.

Aspects of some embodiments include a display device and an electronic device which have relatively improved display quality.

However, these characteristics are provided for illustrative purposes only and are not intended to limit the scope of embodiments according to the present disclosure.

According to some embodiments of the present disclosure, in a method of manufacturing a polycrystalline silicon layer, the method includes forming an amorphous silicon layer on a substrate, dry cleaning the amorphous silicon layer by supplying a reaction gas to the amorphous silicon layer, and irradiating the amorphous silicon layer with a laser beam to form a polycrystalline silicon layer.

According to some embodiments, the reaction gas may include at least hydrogen fluoride gas and ammonia gas.

According to some embodiments, a supply flow rate of the ammonia gas may be greater than a supply flow rate of the hydrogen fluoride gas.

According to some embodiments, the reaction gas may further include an inert gas.

According to some embodiments, the inert gas may be argon.

According to some embodiments, a supply flow rate of the inert gas may be greater than a supply flow rate of the hydrogen fluoride gas.

According to some embodiments, the amorphous silicon layer may be dry cleaned for about 30 seconds to about 120 seconds.

According to some embodiments, a natural oxide layer may be formed on the amorphous silicon layer, the natural oxide layer being removed in the dry cleaning of the amorphous silicon layer.

According to some embodiments, a thickness of the amorphous silicon layer may be in a range of about 300 Å to about 500 Å.

According to some embodiments, a root mean square value of surface roughness of the polycrystalline silicon layer may be 4 nm or less.

According to some embodiments, the dry cleaning of the amorphous silicon layer may include supplying a reaction gas to the amorphous silicon layer to change a natural oxide layer on the amorphous silicon layer into a reaction product and heating the amorphous silicon layer to remove the reaction product.

According to some embodiments, a heating temperature of the amorphous silicon layer may be in a range of about 150° C. to 250° C.

According to some embodiments of the present disclosure, a method of manufacturing a display device includes forming an amorphous silicon layer on a substrate, dry cleaning the amorphous silicon layer by supplying a reaction gas to the amorphous silicon layer, irradiating the amorphous silicon layer with a laser beam to form a polycrystalline silicon layer, etching the polycrystalline silicon layer to form a polycrystalline silicon pattern, forming a gate electrode on the polycrystalline silicon pattern, partially implanting ions into the polycrystalline silicon pattern to form an active pattern, and forming a light-emitting element on the gate electrode.

According to some embodiments, the reaction gas may include at least hydrogen fluoride gas and ammonia gas.

According to some embodiments, the reaction gas may further include an inert gas.

According to some embodiments, a supply flow rate of the inert gas may be greater than a supply flow rate of the hydrogen fluoride gas.

According to some embodiments, the amorphous silicon layer may be dry cleaned for about 30 seconds to about 120 seconds.

According to some embodiments, the dry cleaning of the amorphous silicon layer may include supplying a reaction gas to the amorphous silicon layer to change a natural oxide layer on the amorphous silicon layer into a reaction product and heating the amorphous silicon layer to remove the reaction product.

According to some embodiments of the present disclosure, provided is a display device manufactured by the above-described methods of manufacturing a display device.

According to some embodiments of the present disclosure, an electronic device includes a processor configured to generate a scan input signal, a power module configured to generate a scan input voltage, and the above-described display device configured to receive the scan input signal and the scan input voltage and output a scan signal to a pixel circuit.

Other aspects, features and characteristics will become more apparent from the following drawings, the claims, and the detailed description of the present disclosure.

### BRIEF DESCRIPTION OF THE DRAWINGS

The above and other aspects, features, and characteristics of certain embodiments of the present disclosure will be more apparent from the following description taken in conjunction with the accompanying drawings, in which:

FIG. 1 is a flowchart illustrating a method of manufacturing a polycrystalline silicon layer, according to some embodiments;

FIGS. 2 to 6 are views illustrating methods of manufacturing a polycrystalline silicon layer, according to some embodiments;

FIG. 7 is an enlarged plan view of region A of FIG. 6;

FIG. 8 illustrates surface images of crystallized polycrystalline silicon layers;

FIG. 9 is a schematic plan view of a display device according to some embodiments;

FIG. 10 is an equivalent circuit diagram of a pixel included in the display device of FIG. 9;

FIG. 11 is a cross-sectional view of a display device according to some embodiments;

FIGS. 12 to 18 are cross-sectional views illustrating a method of manufacturing a display device, according to some embodiments;

FIG. 19 is a block diagram of an electronic device according to some embodiments; and

FIG. 20 illustrates schematic views of electronic devices according to some embodiments.

### DETAILED DESCRIPTION

The disclosure may have various modifications and various embodiments, and specific embodiments are illustrated in the drawings and are described in detail in the detailed description. Aspects and features of embodiments according to the present disclosure and methods of achieving the same will become apparent with reference to embodiments described in detail with reference to the drawings. However, the disclosure is not limited to the embodiments described below, and may be implemented in various forms.

In the following embodiments, the terms “first” and “second” are not used in a limited sense and are used to distinguish one component from another component.

In the following embodiments, an expression in the singular includes an expression in the plural unless the content clearly indicates otherwise.

In the following embodiments, it should be understood that terms “include” and/or “have” are used to indicate the presence of stated features or components, but do not preclude the addition of one or more other features or components.

It will be understood that, when a film, region, or element is referred to as being “above” or “on” another film, region, or element, it can be directly on the other film, region, or element, and it may also mean that intervening films, regions, or elements may be present therebetween.

In the drawings, the sizes of elements may be exaggerated or reduced for the convenience of explanation. For example, the size and thickness of each element are arbitrarily illustrated in the drawings for the convenience of explanation, and thus, the disclosure is not necessarily limited thereto.

According to some embodiments, specific processes may be performed in an order different from the stated order. For example, two consecutive processes may be performed substantially simultaneously, or may be carried out in a reverse order from the stated order.

Hereinafter, aspects of some embodiments of the present disclosure will be described in more detail with reference to the accompanying drawings, and in the following description with reference to the drawings, like reference numerals denote like or corresponding components and redundant descriptions thereof will be omitted.

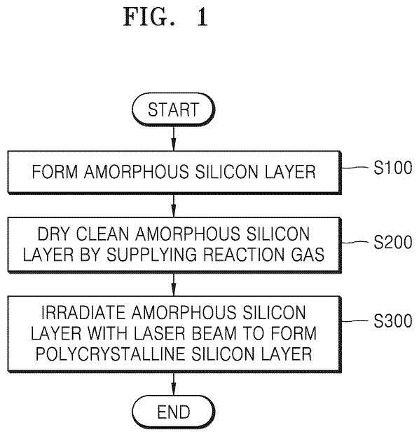

FIG. 1 is a flowchart illustrating aspects of a method of manufacturing a polycrystalline silicon layer, according to some embodiments. Although FIG. 1 illustrates various operations in a method of manufacturing a polycrystalline silicon layer according to some embodiments, embodiments according to the present disclosure are not limited thereto, and according to various embodiments, the method may include additional operations, or fewer operations, or the order of operations may vary, unless otherwise stated or implied, without departing from the spirit and scope of embodiments according to the present disclosure.

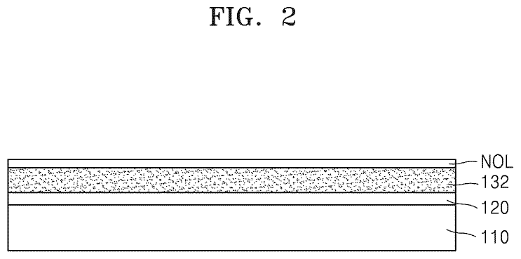

FIGS. 2 to 6 are views illustrating methods of manufacturing a polycrystalline silicon layer, according to some embodiments.

Referring to FIGS. 1 and 2, an amorphous silicon layer 132 may be formed on a substrate 110 (S100).

The substrate 110 may be an insulating substrate including glass, quartz, ceramic, or the like. According to some embodiments, the substrate 110 may be an insulating flexible substrate including plastic, such as polyethylene terephthalate (PET), polyethylene naphthalate (PEN), polyether ether ketone (PEEK), polycarbonate (PC), polyarylate, polyether sulfone (PES), or polyimide (PI). In this regard, a barrier layer including silicon oxide, silicon nitride, amorphous silicon, or the like may also be further formed on the substrate 110.

A buffer layer 120 may be formed on the substrate 110. The buffer layer 120 may provide a flat surface to an upper portion of the substrate 110, and may prevent or reduce instances of impurities or contaminants permeating the substrate 110. For example, the buffer layer 120 may be formed of silicon oxide, silicon nitride, or the like.

An amorphous silicon layer 132 may be formed on the buffer layer 120. The amorphous silicon layer 132 may be formed by a method, such as low-pressure chemical vapor deposition (LPCVD), atmospheric-pressure chemical vapor deposition (APCVD), plasma-enhanced chemical vapor deposition (PECVD), sputtering, or vacuum deposition.

According to some embodiments, a thickness of the amorphous silicon layer 32 may be in a range of about 300 Å to about 500 Å. In case that the thickness of the amorphous silicon layer 132 is less than about 300 Å, the hysteresis characteristics of a thin-film transistor including a polycrystalline silicon layer formed by crystallizing the amorphous silicon layer 132 may deteriorate.

A natural oxide layer NOL may be formed on the amorphous silicon layer 32. The natural oxide layer NOL may be formed through exposure of an upper portion of the amorphous silicon layer 132 to air. In case that the natural oxide layer NOL remains on the amorphous silicon layer 132, a protrusion having a relatively large thickness may be formed on a surface of the polycrystalline silicon layer by the natural oxide layer NOL in the crystallization of the amorphous silicon layer 132 to form a polycrystalline silicon layer.

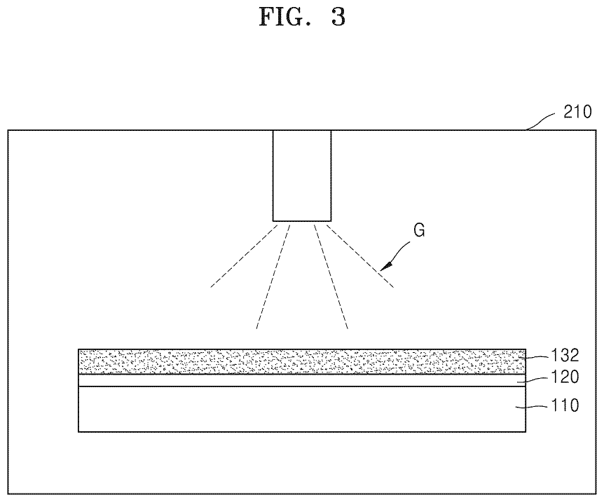

Referring to FIGS. 1 and 3, the amorphous silicon layer 132 may be dry cleaned (S200).

In the dry cleaning of the amorphous silicon layer 132 (S200), first, the substrate 110 on which the amorphous silicon layer 132 is formed may be positioned inside a reaction chamber 210. For example, the substrate 110 on which the amorphous silicon layer 132 is formed may be transferred into the reaction chamber 210 by a transfer device and positioned therein. The amorphous silicon layer 132 may be at room temperature or in a heated state.

Next, a reaction gas G may be injected into the reaction chamber 210. For example, the reaction chamber 210 may have, in an upper surface portion thereof, a supply port configured to provide an injection path for the reaction gas G. The reaction gas G may be supplied into the reaction chamber 210 through the supply port.

The reaction gas G may include elements required to form an etchant for removing the natural oxide layer NOL on the amorphous silicon layer 132. According to some embodiments, the reaction gas G may include at least hydrogen fluoride (HF) gas and ammonia (NH₃) gas, and may further include an inert gas.

A supply flow rate of ammonia gas that is injected into the reaction chamber 210 may be greater than a supply flow rate of hydrogen fluoride gas that is injected into the reaction chamber 210. For example, the supply flow rate of the hydrogen fluoride gas may be in a range of about 60 sccm to about 80 sccm, and the supply flow rate of the ammonia gas may be in a range of about 130 sccm to about 150 sccm.

The inert gas does not directly react with the natural oxide layer NOL on the amorphous silicon layer 132, but may serve to accelerate a reaction by colliding with other materials inside the reaction chamber 210. According to some embodiments, the inert gas may be argon (Ar) gas.

The supply flow rate of the inert gas may be greater than the supply flow rate of the hydrogen fluoride gas. For example, the supply flow rate of the inert gas may be in a range of about 0 sccm to about 100 sccm. In case that the supply flow rate of the inert gas increases, reaction efficiency inside the reaction chamber 210 may deteriorate. Thus, the supply flow rate of the inert gas may be 100 sccm or less.

Hydrogen fluoride gas and ammonia gas contained in the reaction gas G may react to produce ammonium fluoride (NH₄F). Ammonium fluoride produced inside the reaction chamber 210 may react with the natural oxide layer NOL on the amorphous silicon layer 132, and as a result, ammonium hexafluorosilicate ((NH₄)₂SiF₆) may be produced as a reaction product. In this regard, ammonium hexafluorosilicate may be formed as a solid layer.

For example, all or part of silicon oxide present on the surface of the amorphous silicon layer 132 may be changed into a solid layer formed of ammonium hexafluorosilicate, and this process is explained by reaction scheme below.

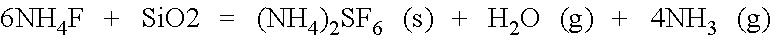

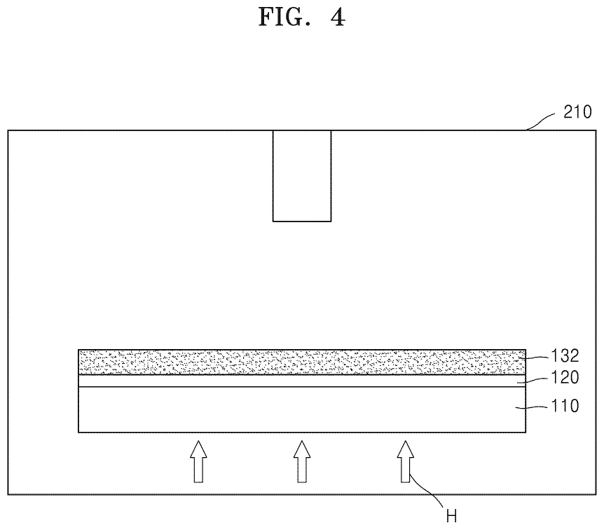

Referring to FIG. 4, heat H may be applied to the amorphous silicon layer 32 in which ammonium hexafluorosilicate is produced, thereby removing the ammonium hexafluorosilicate. According to some embodiments, a heating temperature of the amorphous silicon layer 132 may be in a range of about 150° C. to about 250° C.

For example, the substrate 110 may be positioned on a heated chuck, and heat conduction from the chuck to the substrate 110 may be used to heat the amorphous silicon layer 132. In this regard, the temperature of the heated chuck may be a temperature corresponding to the heating temperature of the amorphous silicon layer 132.

According to some embodiments, the heat H applied to the amorphous silicon layer 132 may be supplied by a heat transfer gas. For example, the amorphous silicon layer 132 may be heated by supplying a heat transfer gas to the amorphous silicon layer 132. For example, the heat transfer gas may include at least heated H₂O, and a temperature of the heat transfer gas may be in a range of about 200° C. to about 1,000° C. The application of the heat H to the amorphous silicon layer 132 to remove the ammonium hexafluorosilicate may be performed in the reaction chamber 210, but embodiments according to the present disclosure are not limited thereto.

The ammonium hexafluorosilicate produced on the surface of the amorphous silicon layer 132 may be vaporized by the supplied heat H, and this process is explained by reaction scheme below.

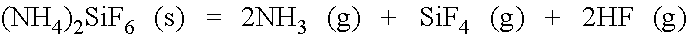

For example, the ammonium hexafluorosilicate produced on the surface of the amorphous silicon layer 132 may be completely removed by the applied heat H. As such, by dry cleaning the amorphous silicon layer 132 with the reaction gas G, the natural oxide layer NOL formed on the amorphous silicon layer 132 may be removed and only the amorphous silicon layer 132 may remain.

According to some embodiments, the dry cleaning of the amorphous silicon layer 132 may be performed for about 30 seconds to about 120 seconds. In case that the amorphous silicon layer 132 is dry cleaned for less than about 30 seconds, the natural oxide layer NOL formed on the amorphous silicon layer 132 may not be sufficiently removed, and grains of the polycrystalline silicon layer formed thereafter may not grow sufficiently.

According to some embodiments, the reaction gas G and the heat H may be supplied simultaneously while the dry cleaning process is performed, but embodiments according to the present disclosure are not limited thereto.

Referring to FIGS. 1, 5, and 6, the amorphous silicon layer 132 may be crystallized to form a polycrystalline silicon layer 134 (S300).

The polycrystalline silicon layer 134 may be formed by irradiating the amorphous silicon layer 132 with a laser beam L. A laser 230 may intermittently generate the laser beam L to irradiate the amorphous silicon layer 132 with the laser beam L.

For example, the laser 230 may be an excimer laser that generates the laser beam L with short wavelength, high power output, and high efficiency. For example, the excimer laser may include an inert gas, an inert gas halide, a mercury halide, an inert gas acid compound, a polyatomic excimer, and the like. For example, the inert gas may be Ar₂, Kr₂, Xe₂, or the like, the inert gas halide may be ArF, ArCl, KrF, KrCl, XeF, XeCl, or the like, the mercury halide may be HgCl, HgBr, HgI, or the like, the inert gas acid compound may be ArO, KrO, XeO, or the like, and the polyatomic excimer may be Kr₂F, Xe₂F, or the like.

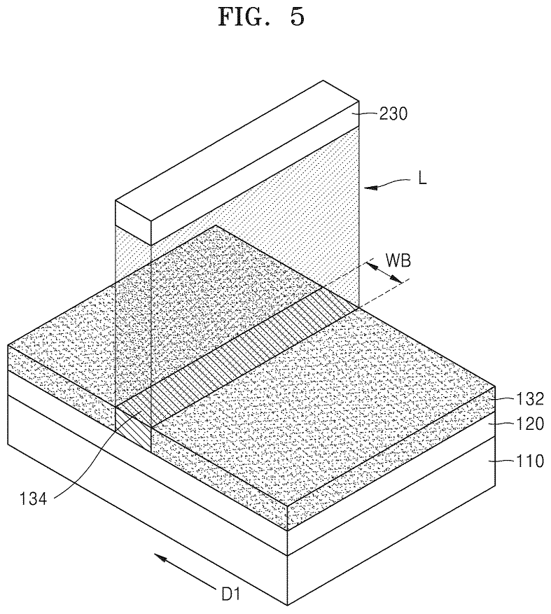

The laser 230 may irradiate the amorphous silicon layer 132 with the laser beam L while the substrate 110 is moved in a first direction D1, thereby crystallizing the amorphous silicon layer 132 into the polycrystalline silicon layer 134. As illustrated in FIG. 5, in a region where the crystallization process is performed using the laser beam L, the amorphous silicon layer 132 may be converted into the polycrystalline silicon layer 134. According to some embodiments, a wavelength of the laser beam L irradiated onto the amorphous silicon layer 132 may be about 308 nm.

The laser 230 may irradiate the amorphous silicon layer 132 with the laser beam L having an energy density of about 440 mJ/cm² to about 550 mJ/cm². In case that the energy density of the laser beam L is less than about 440 mJ/cm², a grain size of the polycrystalline silicon layer 134 may be relatively small. In case that the energy density of the laser beam L is greater than about 550 mJ/cm², the amorphous silicon layer 132 may be completely liquefied by the laser beam L, and crystal seeds for silicon crystallization may not be formed.

According to some embodiments, a width WB in the first direction D1 of the laser beam L may be about 480 μm, and a scan pitch in the first direction D1 of the laser beam L may be in a range of about 9 μm to about 30 μm. For example, in case that the scan pitch is about 24 μm, a certain area of the amorphous silicon layer 132 may be irradiated with the laser beam L about 24 times.

In case that the amorphous silicon layer 132 in a solid state is irradiated with the laser beam L, the amorphous silicon layer 132 may absorb heat and change into a liquid state, and then may change back to the solid state through heat dissipation. In this regard, crystals may grow from crystal seeds, resulting in the formation of grains. In case that the scan pitch of the laser beam L is about 9 μm or less, the polycrystalline silicon layer 134 having a relatively large grain size may be formed.

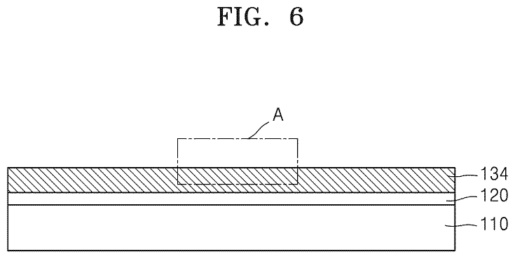

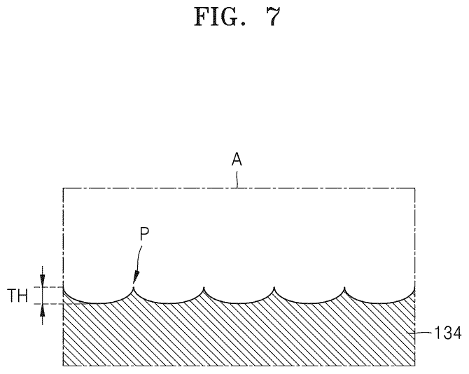

FIG. 7 is an enlarged plan view of region A of FIG. 6. For example, FIG. 7 is an enlarged cross-sectional view of the polycrystalline silicon layer 134 of FIG. 6.

A protrusion P may be formed on the surface of the polycrystalline silicon layer 134 on which the crystallization process has been performed. For example, the amorphous silicon layer 132 melted by the laser beam L may be recrystallized, thereby forming the protrusion P.

The protrusion P may protrude upward from the surface of the polycrystalline silicon layer 134 and have a sharp-ended shape. The protrusion P may have a constant thickness TH corresponding to a distance from the surface of the polycrystalline silicon layer 134 to the end of the protrusion P.

A root mean square (RMS) value of surface roughness of the polycrystalline silicon layer 134 may be about 4 nm or less. In this regard, the thickness TH of the protrusion P formed on the surface of the polycrystalline silicon layer 134 may have an RMS value of about 4 nm or less.

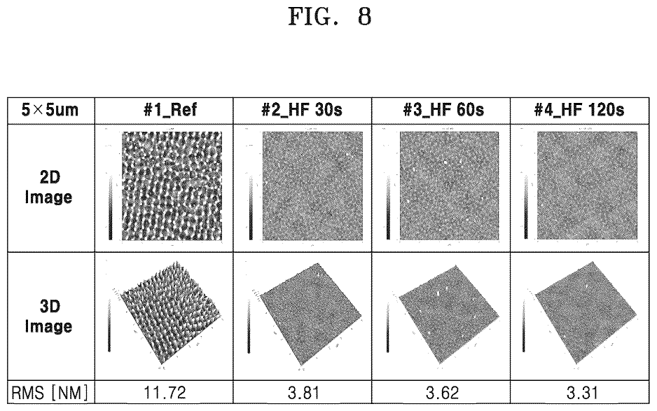

FIG. 8 illustrates surface images of the polycrystalline silicon layers 134 crystallized.

In FIG. 8, #1 image is a surface image of the polycrystalline silicon layer crystallized without dry cleaning the amorphous silicon layer, and #2 to #4 images are surface images of the polycrystalline silicon layers 134 obtained by, before a crystallization process, dry cleaning the amorphous silicon layers 132 for 30 seconds, 60 seconds, and 120 seconds, respectively, followed by crystallization.

Referring to FIG. 8, it can be seen that, in case that the amorphous silicon layer is crystallized without dry cleaning, the polycrystalline silicon layer may have a protrusion having a relatively large thickness on a surface thereof, and it can be seen that, in case that the amorphous silicon layers 132 are dry cleaned for 30 seconds, 60 seconds, and 120 seconds, respectively, followed by crystallization, the polycrystalline silicon layers 134 may each have a protrusion P having a significantly reduced thickness on a surface thereof.

It can also be seen that, as the dry cleaning time of the amorphous silicon layer 132 increases from 30 seconds to 60 seconds to 120 seconds, the RMS value of surface roughness decreases, and in case that the dry cleaning time is 30 seconds, the RMS value of surface roughness is 3.81 nm, which falls within 4 nm or less.

As such, in the method of manufacturing a polycrystalline silicon layer, according to some embodiments of the present disclosure, before the crystallization process, the amorphous silicon layer 132 may be dry cleaned for a certain period of time, thereby relatively reducing the thickness of the protrusion P due to crystallization, and the polycrystalline silicon layer 134 with relatively small surface roughness may be formed.

Also, the method of manufacturing a polycrystalline silicon layer, according to some embodiments of the present disclosure, may prevent or reduce the occurrence of circular spots on a surface of the polycrystalline silicon layer, caused by residual moisture in case that a wet cleaning process is used to remove the natural oxide layer NOL on the amorphous silicon layer 132. For example, in the method of manufacturing a polycrystalline silicon layer, according to some embodiments of the present disclosure, by dry cleaning the amorphous silicon layer 132 using the reaction gas G, no moisture remains on the surface of the amorphous silicon layer 132, and circular spots do not occur. Also, a polycrystalline silicon layer manufactured, according to some embodiments of the present disclosure, does not require a separate capping layer for relatively improving circular spots, and thus the distribution of line spots and edge residual film spots caused by the capping layer may be relatively improved, resulting in relatively improved reliability of a device.

The dry cleaning process and crystallization process for forming the polycrystalline silicon layer 134 have been described with reference to FIGS. 1 to 6, but embodiments according to the present disclosure are not limited thereto. For example, in addition to the above processes, processes for forming the polycrystalline silicon layer 134 may be added, or some of the above processes may be omitted. In some embodiments, the processes may also be performed a plurality of times. For example, the crystallization process may be performed two or more times.

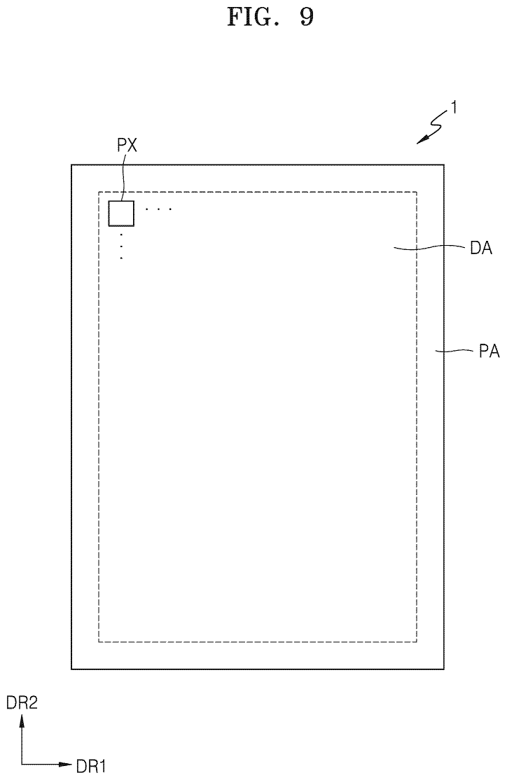

FIG. 9 is a schematic plan view of a display device 1 according to some embodiments.

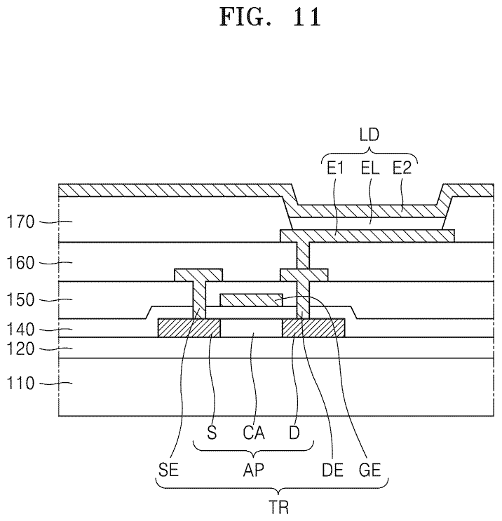

Referring to FIG. 9, the display device 1 may include a display area DA in which a plurality of pixels PX are arranged and a peripheral area PA located outside the display area DA. For example, the peripheral area PA may entirely surround the display area DA. This may also be understood that the substrate 110 (see FIG. 11) included in the display device 1 has the display area DA and the peripheral area PA.

Each of the plurality of pixels PX of the display device 1 is an area capable of emitting light of a certain color, and the display device 1 may provide an image by using light emitted from the pixels PX. For example, each pixel PX may emit red light, green light, blue light, or white light. Each of the pixels PX refers to a sub-pixel and may include a display element and a pixel circuit connected thereto. The display element may include an organic light-emitting diode, a quantum dot organic light-emitting diode, or the like.

The plurality of pixels PX may be arranged in the form of a matrix in the first direction DR1 and a second direction DR2. The first direction DR1 and the second direction DR2 may be defined as intersecting directions.

The display area DA may have a shape, such as a polygon including a square, as illustrated in FIG. 9. For example, the display area DA may have a rectangular shape that extends longer in the second direction DR2 than in the first direction DR1. According to some embodiments, the display area DA may have various shapes, such as an ellipse or a circle.

The peripheral area PA may be a non-display area in which the pixels PX are not arranged. A driver configured to provide electrical signals or power to the pixels PX, or the like may be arranged in the peripheral area PA. In the peripheral area PA, pads to which various electronic components or printed circuit boards may be electrically connected may be arranged. The respective pads may be spaced apart from each other in the peripheral area PA, and may be electrically connected to a printed circuit board or an integrated circuit device.

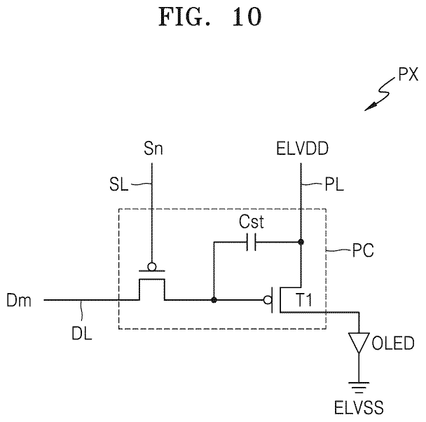

FIG. 10 is an equivalent circuit diagram of a pixel PX included in the display device 1 of FIG. 9. Although FIG. 10 illustrates various components in a pixel according to some embodiments, embodiments according to the present disclosure are not limited thereto, and according to various embodiments, the pixel may include additional components without departing from the spirit and scope of embodiments according to the present disclosure.

Referring to FIG. 10, the pixel PX may include a pixel circuit PC connected to a scan line SL and a data line DL, and an organic light-emitting diode OLED connected to the pixel circuit PC.

The pixel circuit PC may include a driving thin-film transistor (TFT) T1, a switching TFT T2, and a storage capacitor Cst. The switching TFT T2 may be connected to the scan line SL and the data line DL, and a data signal Dm input through the data line DL may be transmitted to the driving TFT T1 according to a scan signal Sn input through the scan line SL.

The storage capacitor Cst may be connected to the switching TFT T2 and a driving voltage line PL, and may store a voltage corresponding to the difference between a voltage received from the switching TFT T2 and a driving voltage ELVDD supplied to the driving voltage line PL.

The driving TFT T1 may be connected to the driving voltage line PL and the storage capacitor Cst, and may control a driving current flowing through the organic light-emitting diode OLED from the driving voltage line PL in response to a voltage value stored in the storage capacitor Cst. The organic light-emitting diode OLED may emit light with a certain brightness according to a driving current. A counter electrode of the organic light-emitting diode OLED may be supplied with an electrode power voltage ELVSS.

Although FIG. 10 illustrates that the pixel circuit PC includes two transistors and one storage capacitor, embodiments according to the present disclosure are not limited thereto. For example, the number of transistors or the number of storage capacitors may vary depending on the design of the pixel circuit PC.

FIG. 11 is a cross-sectional view of the display device 1 according to some embodiments.

Referring to FIG. 11, the display device 1 according to some embodiments of the present disclosure may include the substrate 110, a TFT TR arranged on the substrate 110, and a display element LD arranged on the TFT TR. The TFT TR and the display element LD as illustrated in FIG. 11 may correspond to the driving TFT T1 and the organic light-emitting diode OLED, respectively, as illustrated in FIG. 10. The display device 1 may include an organic light-emitting diode as the display element LD, but embodiments according to the present disclosure are not limited thereto.

The TFT TR may include an active pattern AP, a gate insulating layer 140, a gate electrode GE, a source electrode SE, and a drain electrode DE, which are sequentially stacked. The TFT TR may perform a switching operation that allows current to flow through the active pattern AP on the basis of a signal applied to the gate electrode GE.

The TFT TR may have a top gate structure in which the gate electrode GE is positioned above the active pattern AP. However, embodiments according to the present disclosure are not limited thereto, and the TFT TR may also have a bottom gate structure in which the gate electrode is positioned below the active pattern.

The display element LD may include a first electrode E1, an emission layer EL, and a second electrode E2, which are sequentially stacked. The display element LD may display an image by emitting light on the basis of a driving current transmitted from the TFT TR.

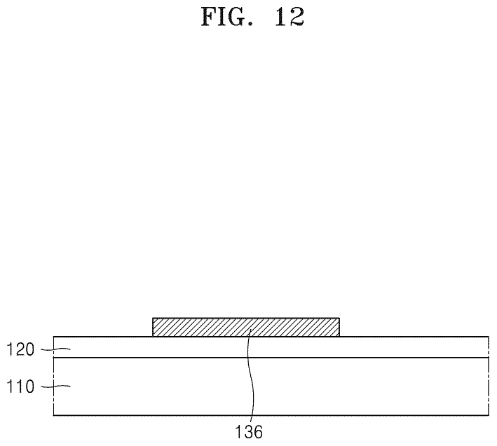

FIGS. 12 to 18 are cross-sectional views illustrating a method of manufacturing a display device, according to some embodiments. Hereinafter, some descriptions redundant to those of the method of manufacturing a polycrystalline silicon layer with reference to FIGS. 1 to 6 may be omitted.

Referring to FIGS. 6 and 12, the buffer layer 120 and the polycrystalline silicon layer 134 may be sequentially formed on the substrate 110, and the polycrystalline silicon layer 134 may be etched to form a polycrystalline silicon pattern 36. For example, the polycrystalline silicon layer 134 may be etched by photolithography. For example, a photoresist pattern may be formed on the polycrystalline silicon layer 134 by using an exposure process and a development process, and the polycrystalline silicon layer 134 may be etched using the photoresist pattern as an etch stop layer.

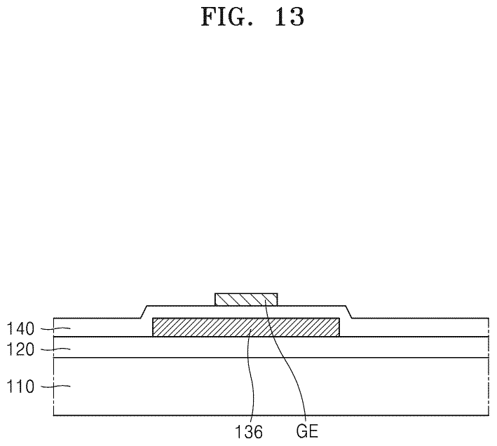

Referring to FIG. 13, the gate insulating layer 140 may be formed on the polycrystalline silicon pattern 136, and the gate electrode GE may be formed on the gate insulating layer 140.

The gate insulating layer 140 may be arranged on the buffer layer 120 to cover the polycrystalline silicon pattern 136. The gate insulating layer 140 may insulate the gate electrode GE from the polycrystalline silicon pattern 136.

According to some embodiments, an RMS value of surface roughness of the polycrystalline silicon pattern 136 may be about 4 nm. In this regard, due to relatively small surface roughness of the polycrystalline silicon pattern 136, the gate insulating layer 140 formed on the polycrystalline silicon pattern 136 may be formed to have a relatively thin thickness. For example, the gate insulating layer 140 may be formed to a thickness of about 30 nm to about 200 nm.

The gate insulating layer 140 may include an inorganic insulating material. Examples of inorganic insulating materials that may be used in the gate insulating layer 140 may include silicon oxide, silicon nitride, silicon oxynitride, and the like. These may be used alone or a combination thereof may be used.

The gate electrode GE may overlap the polycrystalline silicon pattern 136. The gate electrode GE may include a conductive material. Examples of conductive materials that may be used in the gate electrode GE may include aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), copper (Cu), and the like. These may be alone or a combination thereof may be used.

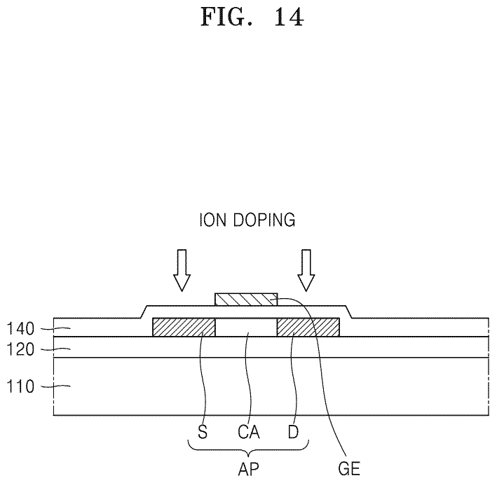

Referring to FIG. 14, the active pattern AP may be formed by partially implanting ions into the polycrystalline silicon pattern 136.

By partially doping the polycrystalline silicon pattern 136 through an ion implantation process, the active pattern AP including a source area S, a drain area D, and a channel area CA may be formed. The channel area CA may be formed between the source area S and the drain area D. For example, the ions may be n-type impurities or p-type impurities.

According to some embodiments, a portion of the polycrystalline silicon pattern 136 that overlaps the gate electrode GE may remain undoped with ions, and thus may be formed as the channel area CA. Portions of the polycrystalline silicon pattern 136 that are doped with ions may have the properties of a conductor due to increased conductivity thereof, and thus may be formed as the source area S and the drain area D.

According to some embodiments, by doping impurities at lower concentrations than those in the ion implantation process, low-concentration doping areas may be formed respectively between the channel area CA and the source area S and between the channel area CA and the drain area D. The low-concentration doping regions may serve as buffers in the active pattern AP, and thus may relatively improve the electrical characteristics of a TFT.

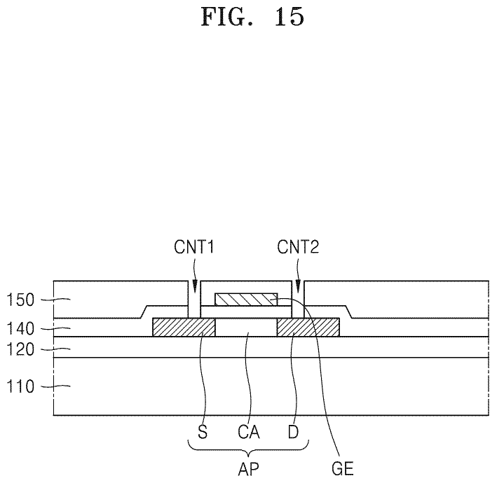

Referring to FIG. 15, an interlayer insulating layer 150 may be formed on the gate electrode GE. The interlayer insulating layer 150 may be arranged on the gate insulating layer 140 to cover the gate electrode GE.

The interlayer insulating layer 150 may include an inorganic insulating material, an organic insulating material, or a combination thereof. Examples of inorganic insulating materials that may be used in the interlayer insulating layer 150 may include silicon oxide, silicon nitride, silicon oxynitride, and the like. Examples of organic insulating materials that may be used in the interlayer insulating layer 150 may include polyimide, polyamide, acrylic resin, phenol resin, benzocyclobutene (BCB), and the like. The interlayer insulating layer 150 may insulate the source electrode SE and the drain electrode DE from the gate electrode GE.

Portions of the interlayer insulating layer 150 and the gate insulating layer 40 may be etched to form a first contact hole CNT1 and a second contact hole CNT2. The first contact hole CNT1 may expose the source area S of the active pattern AP, and the second contact hole CNT2 may expose the drain area D of the active pattern AP.

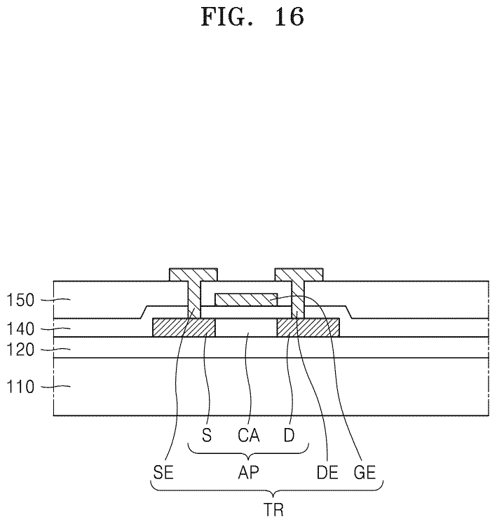

Referring to FIG. 16, the source electrode SE and the drain electrode DE may be formed on the interlayer insulating layer 150. The source electrode SE may be connected to the source area S of the active pattern AP, and the drain electrode DE may be connected to the drain area D of the active pattern AP. For example, the source electrode SE may contact the source area S through the first contact hole CNT1, and the drain electrode DE may contact the drain area D through the second contact hole CNT2.

Each of the source electrode SE and the drain electrode DE may include a conductive material. Examples of conductive materials that may be used in each of the source electrode SE and the drain electrode DE may include aluminum, platinum, palladium, silver, magnesium, gold, nickel, neodymium, iridium, chromium, lithium, calcium, molybdenum, titanium, tungsten, copper, and the like. These may be used alone or a combination thereof may be used.

The active pattern AP, the gate electrode GE, the source electrode SE, and the drain electrode DE may form the TFT TR.

According to some embodiments, before the crystallization process, the amorphous silicon layer 132 may be dry cleaned using a reaction gas containing hydrogen fluoride and ammonia, and a crystallization process may be performed by irradiating a laser beam with relatively high energy density at a relatively small scan pitch, thereby forming a TFT TR including the active pattern AP having a relatively large grain size and relatively low surface roughness.

In case that the grain size of the active pattern AP is large, the number of grain boundaries per unit area may be relatively reduced, and thus the charge mobility of the TFT TR including such an active pattern AP may increase. In some embodiments, because the active pattern AP has relatively small surface roughness, an area of an interface between the active pattern AP and the gate insulating layer 140 positioned on the active pattern AP may be small, and the hysteresis characteristics of the TFT TR including the active pattern AP may be relatively improved.

Table 1 shows the threshold voltage and hysteresis characteristics of each of a TFT manufactured according to Comparative Example without dry cleaning an amorphous silicon layer and a TFT TR including the active pattern AP having relatively small surface roughness, manufactured according to some embodiments of the present disclosure, by, before a crystallization process, dry cleaning the amorphous silicon layer 132, followed by crystallization.

TABLE 1

| | Comparative Example | Example |
|---|---|---|
| Threshold voltage (V) | −3.0 | −3.3 |
| Hysteresis (V) | 0.23 | 0.15 |

Referring to Table 1, it can be seen that the threshold voltage of the TFT TR according to some embodiments of the present disclosure is smaller than that of the TFT according to Comparative Example, and it can also be seen that the hysteresis characteristics of the TFT TR according to some embodiments of the present disclosure have a smaller value than those of the TFT according to Comparative Example. Therefore, the display device 1 according to some embodiments of the present disclosure may include the TFT TR with relatively improved hysteresis characteristics.

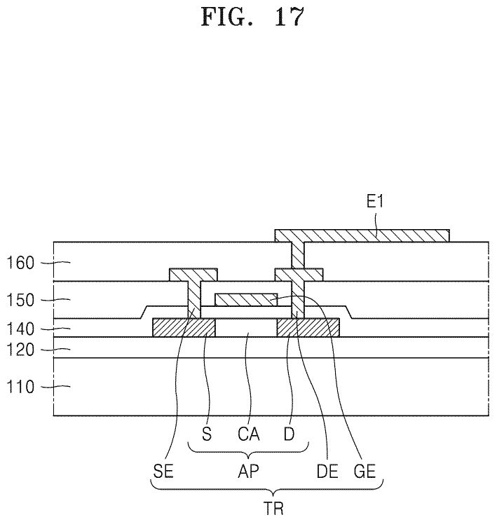

Referring to FIG. 17, a via insulating layer 160 may be formed on the source electrode SE and the drain electrode DE, and the first electrode E1 may be formed on the via insulating layer 160. The via insulating layer 160 may be arranged on the interlayer insulating layer 150 to cover the source electrode SE and the drain electrode DE.

The via insulating layer 160 may include an organic insulating material. Examples of organic insulating materials that may be used in the via insulating layer 60 may include photoresist, polyacrylic resin, polyimide resin, acrylic resin, and the like. These may be used alone or a combination thereof may be used. The via insulating layer 160 may insulate the first electrode E1 from the source electrode SE or the drain electrode DE.

The first electrode E1 may contact the drain electrode DE through a contact hole formed by removing a portion of the via insulating layer 160. The first electrode E1 may include a conductive material. Examples of conductive materials that may be used in the first electrode E1 may include aluminum, platinum, palladium, silver, magnesium, gold, nickel, neodymium, iridium, chromium, lithium, calcium, molybdenum, titanium, tungsten, copper, indium tin oxide, indium zinc oxide, and the like. These may be used alone or a combination thereof may be used.

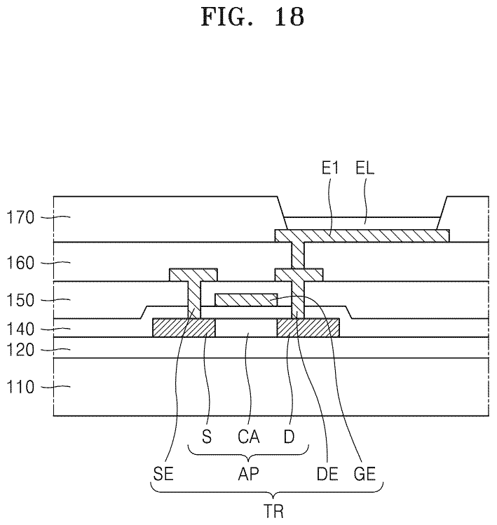

Referring to FIG. 18, a pixel defining layer 170 may be formed on the via insulating layer 160, and the emission layer EL may be formed on the first electrode E1. An opening that exposes at least a portion of the first electrode E1 may be defined in the pixel defining layer 170.

The pixel defining layer 170 may include an organic insulating material. Examples of organic insulating materials that may be used in the pixel defining layer 70 may include photoresist, polyacrylic resin, polyimide resin, acrylic resin, and the like. These may be used alone or a combination thereof may be used.

The emission layer EL may be formed on the first electrode E1 exposed through the opening of the pixel defining layer 170. For example, the emission layer EL may be formed by a method, such as screen printing, inkjet printing, deposition, or the like. The emission layer EL may be formed of an organic material and may emit light of a preset color.

For example, the organic material for forming the emission layer EL may include small-molecule organic compounds, such as copper phthalocyanine, N,N′-diphenylbenzidine, and tris-(8-hydroxyquinoline)aluminum, and may include polymeric organic compounds, such as poly(3,4-ethylenedioxythiophene, polyaniline, polyphenylenevinylene, and polyfluorene.

According to some embodiments, a hole injection layer and/or a hole transport layer may further be formed between the first electrode E1 and the emission layer EL, or an electron transport layer and/or an electron injection layer may further be formed on the emission layer EL.

Referring back to FIG. 11, the second electrode E2 may be formed on the emission layer EL and the pixel defining layer 170. The second electrode E2 may be a common electrode of the display device 1. The second electrode E2 may be formed as a transmissive electrode or a reflective electrode depending on the emission type of the display device. For example, in case that the second electrode E2 is formed as a transmissive electrode, the second electrode E2 may include lithium (Li), calcium (Ca), lithium fluoride (LiF), aluminum (AI), magnesium (Mg), or a combination thereof.

The first electrode E1, the emission layer EL, and the second electrode E2 may form the display element LD. The display element LD may emit light on the basis of a driving current provided from the TFT TR.

The display device 1 according to some embodiments of the present disclosure may be applied to various electronic devices. The electronic device according to some embodiments may include the display device 1 as described above, and may further include a module or device having additional functions in addition to the display device 1.

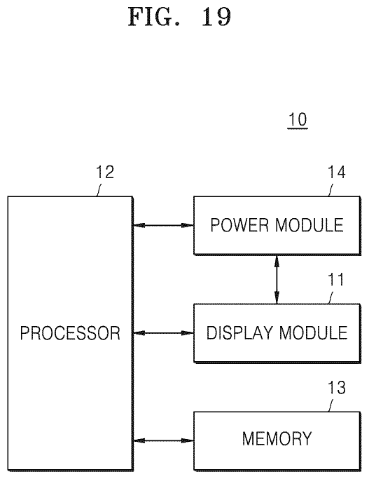

FIG. 19 is a block diagram of an electronic device 10 according to some embodiments. Referring to FIG. 19, the electronic device 10 according to some embodiments of the present disclosure may include a display module 11, a processor 2, a memory 13, and a power module 14.

The processor 12 may include at least one of a central processing unit (CPU), an application processor (AP), a graphic processing unit (GPU), a communication processor (CP), an image signal processor (ISP), or a controller.

Data information required to operate the processor 12 or the display module 1 may be stored in the memory 13. In case that the processor 12 executes an application stored in the memory 13, an image data signal and/or an input control signal may be transmitted to the display module 11, and the display module 11 may process the received signal and output image information through a display screen.

The power module 14 may include a power supply module, such as a power adapter or a battery device, and a power conversion module configured to convert power supplied by the power supply module to generate power required for operation of the electronic device 10.

At least one of the components of the electronic device 10 as described above may be included in the display device according to the above-described embodiments. According to some embodiments, some of the individual modules functionally included in a single module may be included in the display device, and others thereof may be provided separately from the display device. For example, the display device may include the display module 11, and the processor 12, the memory 3, and the power module 14 may be provided in the form of other devices in the electronic device 10, not in the display device.

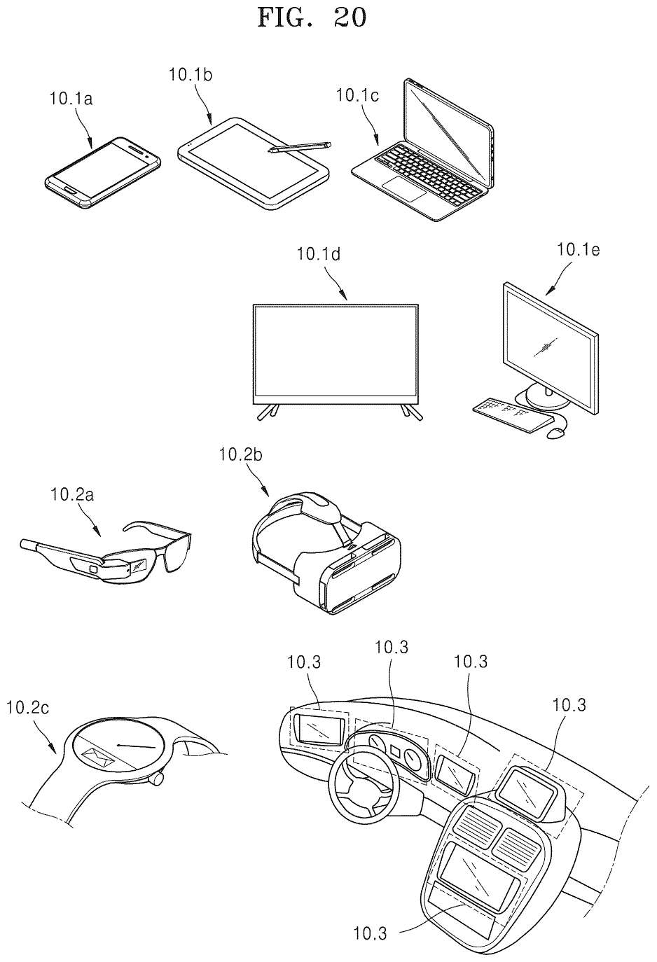

FIG. 20 illustrates schematic views of electronic devices according to various embodiments.

Referring to FIG. 20, various electronic devices according to embodiments, to which the display device is applied, may include: electronic devices for displaying an image, such as an smartphone 10.1a, a tablet PC 10.1b, a laptop 10.1c, a TV 10.1d, and a desktop monitor 10.1e; wearable electronic devices including display modules, such as smart glasses 10.2a, a head-mounted display 10.2b, and a smart watch 10.2c; electronic devices 10.3 for a vehicle, including display modules such as a center information display (CID) positioned in an automobile instrument panel, a center fascia, and a dashboard, and a room mirror display.

In a method of manufacturing a polycrystalline silicon layer, according to some embodiments of the present disclosure, by dry cleaning an amorphous silicon layer before crystallization of the amorphous silicon layer, surface roughness of a polycrystalline silicon layer may be relatively reduced.

A display device and an electronic device, according to embodiments of the present disclosure, may include a thin film transistor having an active pattern with relatively small surface roughness, and thus dispersion in the threshold voltage of the thin-film transistor may be relatively reduced, and a gate insulating layer arranged on the active pattern may not be damaged.

However, these effects are not intended to limit the scope of the present disclosure, and may be expanded in various ways without departing from the spirit and scope of the present disclosure.

Aspects of some embodiments of the present disclosure have been described with reference to some embodiments as illustrated in the drawings, but the disclosed embodiments are provided for illustrative purposes only, and it will be understood by one of ordinary skill in the art that various modifications and modified embodiments can be made therefrom. Thus, the true technical scope of embodiments according to the present disclosure should be defined by the technical idea of the appended claims, and their equivalents.

What is claimed is:

1. A method of manufacturing a polycrystalline silicon layer, comprising:
forming an amorphous silicon layer on a substrate;
dry cleaning the amorphous silicon layer by supplying a reaction gas to the amorphous silicon layer; and
irradiating the amorphous silicon layer with a laser beam to form a polycrystalline silicon layer.

2. The method of claim 1, wherein the reaction gas comprises at least hydrogen fluoride gas and ammonia gas.

3. The method of claim 2, wherein a supply flow rate of the ammonia gas is greater than a supply flow rate of the hydrogen fluoride gas.

4. The method of claim 2, wherein the reaction gas further comprises an inert gas.

5. The method of claim 4, wherein the inert gas is argon.

6. The method of claim 4, wherein a supply flow rate of the inert gas is greater than a supply flow rate of the hydrogen fluoride gas.

7. The method of claim 1, wherein the amorphous silicon layer is dry cleaned for 30 seconds to 120 seconds.

8. The method of claim 1, wherein a natural oxide layer is formed on the amorphous silicon layer, the natural oxide layer being removed in the dry cleaning of the amorphous silicon layer.

9. The method of claim 1, wherein a thickness of the amorphous silicon layer is in a range of 300 Å to 500 Å.

10. The method of claim 1, wherein a root mean square value of surface roughness of the polycrystalline silicon layer is 4 nanometers (nm) or less.

11. The method of claim 1, wherein
dry cleaning the amorphous silicon layer comprises:
supplying a reaction gas to the amorphous silicon layer to change a natural oxide layer on the amorphous silicon layer into a reaction product; and
heating the amorphous silicon layer to remove the reaction product.

12. The method of claim 11, wherein a heating temperature of the amorphous silicon layer is in a range of 150° C. to 250° C.

13. A method of manufacturing a display device, comprising:
forming an amorphous silicon layer on a substrate;
dry cleaning the amorphous silicon layer by supplying a reaction gas to the amorphous silicon layer;
irradiating the amorphous silicon layer with a laser beam to form a polycrystalline silicon layer;
etching the polycrystalline silicon layer to form a polycrystalline silicon pattern;
forming a gate electrode on the polycrystalline silicon pattern;
partially implanting ions into the polycrystalline silicon pattern to form an active pattern; and
forming a light-emitting element on the gate electrode.

14. The method of claim 13, wherein the reaction gas comprises at least hydrogen fluoride gas and ammonia gas.

15. The method of claim 14, wherein the reaction gas further comprises an inert gas.

16. The method of claim 15, wherein a supply flow rate of the inert gas is greater than a supply flow rate of the hydrogen fluoride gas.

17. The method of claim 13, wherein the amorphous silicon layer is dry cleaned for 30 seconds to 120 seconds.

18. The method of claim 13, wherein
dry cleaning the amorphous silicon layer comprises:
supplying a reaction gas to the amorphous silicon layer to change a natural oxide layer on the amorphous silicon layer into a reaction product; and
heating the amorphous silicon layer to remove the reaction product.

19. A display device manufactured by the method according to claim 13.

20. An electronic device comprising:
a processor configured to generate a scan input signal;
a power module configured to generate a scan input voltage; and
the display device of claim 19 configured to receive the scan input signal and the scan input voltage and to output a scan signal to a pixel circuit.
